(19) United States
(12) Patent Application Publication
(10) Pub. No.: US 2011/0070744 A1
(43) Pub. Date: Mar. 24, 2011

(54) Silicon Texturing Formulations for Solar Applications

(76) Inventors: Zhi-Wen Sun, San Jose, CA (US); Minh Anh Nguyen, San Jose, CA (US)

(21) Appl. No.: 12/885,360

(22) Filed: Sep. 17, 2010

Related U.S. Application Data
(60) Provisional application No. 61/243,998, filed on Sep. 18, 2009.

(51) Int. Cl. H01L 21/306; C09K 13/02

(52) U.S. Cl. 438/753; 252/79.5; 257/E21.219

(57) ABSTRACT

The current invention describes a process and texturing solution for texturing a crystalline silicon substrate to provide a light trapping surface within a crystalline silicon based solar cell. In an embodiment the texturing process includes a pre-treatment of hydrofluoric acid followed by the application of a texturing solution that includes potassium hydroxide (KOH) and butanol. The application of the texturing solution may be followed by a hydrofluoric acid post-treatment. A combinatorial method of optimizing the textured surface of a crystalline silicon substrate is also described.

### FIELD OF THE INVENTION

The present invention relates generally to semiconductor processing. More specifically, a process and texturing solution for texturing a crystalline silicon substrate for use in a silicon based solar cell is described.

### BACKGROUND OF THE INVENTION

Silicon based solar cells typically include a textured crystalline silicon surface. The texturing is commonly created by a mixture of an acid, potassium hydroxide (KOH) and isopropyl alcohol (IPA). But, this texturing formulation has limitations that prevent the formation of efficient solar cells. For example, there are often flat untextured regions on the textured surface of the crystalline silicon substrate and using this formulation it is difficult to control the sizes of the pyramids formed on the surface. The light trapping efficiency of the solar cell is not optimal when the pyramid texture is formed of many different sized pyramids and when there are flat untextured regions on the surface of the crystalline silicon substrate. Additionally, the process window for the KOH and IPA texturing formulation is narrow, making it difficult to use in production. The boiling point of IPA is relatively low at 84.2° C. The texturing formulation of KOH and IPA is typically used at a temperature of approximately 80° C. and cannot be raised much higher due to the boiling point of IPA. Evaporation of the IPA also creates a challenge because the composition of the texturing solution changes over time and may not provide consistent texturing from one substrate to another.

### BRIEF DESCRIPTION OF THE DRAWINGS

Various embodiments of the invention are disclosed in the following detailed description and the accompanying drawings:

FIG. 1 is a flowchart describing a process for texturing a crystalline silicon substrate according to various embodiments;

FIGS. 2A-2C illustrate SEM photographs of textured crystalline silicon substrates according to various embodiments;

FIG. 3 is a diagram describing an example of a combinatorial funnel for screening samples;

FIG. 4 is a flowchart describing a combinatorial method of tuning a silicon texturing solution to texture a crystalline silicon substrate to have predetermined characteristics; and

FIG. 5 is an example of a crystalline silicon substrate having defined regions for combinatorial processing.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The current invention describes a process and texturing solution for texturing a crystalline silicon substrate to provide a light trapping surface within a crystalline silicon based solar cell. In an embodiment, the texturing process includes a pre-treatment of hydrofluoric acid followed by the application of a texturing solution that includes potassium hydroxide (KOH) and butanol. The application of the texturing solution may be followed by a hydrofluoric acid post-treatment. A combinatorial method of optimizing the textured surface of a crystalline silicon substrate is also described.

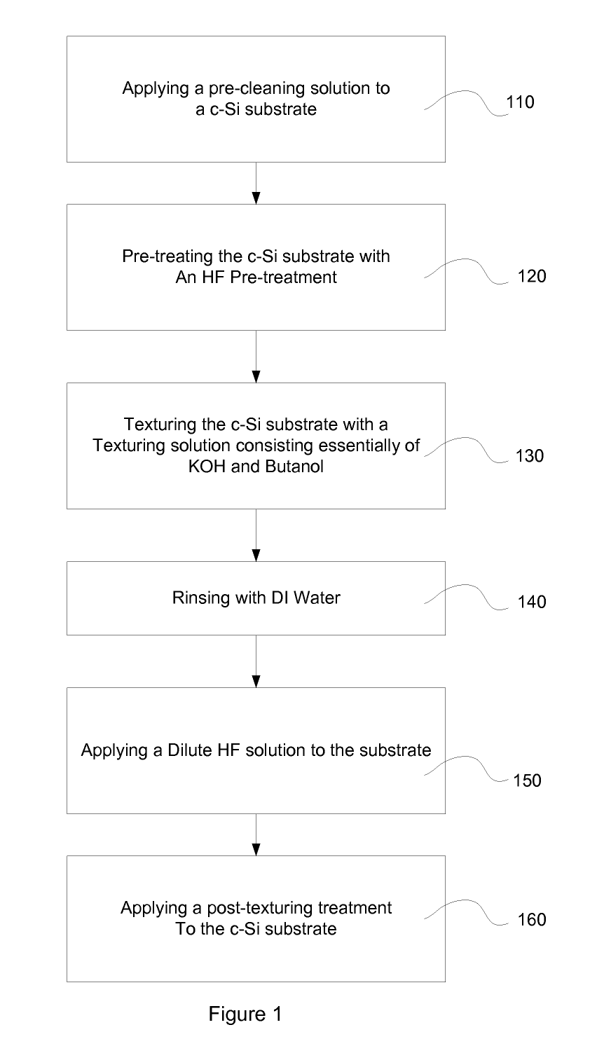

FIG. 1 shows a flow-chart of various embodiments of texturing a crystalline silicon substrate for use in a crystalline silicon based solar cell. Crystalline silicon based solar cells are much more efficient when the silicon substrate is capable of trapping light because greater conversion of that light to energy can occur. Therefore, it is highly beneficial to texture crystalline silicon substrates as part of the production of solar cells made of the same. In embodiments of the current invention the texturing process may include all or some of the individual processes described in the flowchart of FIG. 1.

In one particular embodiment of the current invention the texturing process may include applying a pre-cleaning solution to a crystalline silicon substrate at block 110 of the flowchart of FIG. 1. The crystalline silicon substrate may be monocrystalline or multicrystalline silicon. The monocrystalline silicon substrate may be in a circular wafer form, such as those used in semiconductor processing. The multicrystalline silicon substrates may be rectangular or square having dimensions of 128 mm×128 mm or 154 mm×154 mm. The pre-cleaning solution may be applied to remove any contaminants from the surface of the substrate that remain after the cutting process or contaminants adhering to the surface during transport and handling of the substrate. The pre-cleaning process may in particular remove organic contaminants that could interfere with the subsequent texturing process. It is hypothesized that organic materials can act as points of nucleation for the texturing process and can potentially interfere with the formation of the intended texture and prevent substrate to substrate texture uniformity. The pre-cleaning solution may be a solvent such as acetone that is good at removing organic contaminants or a commercial cleaning formulation such as SC1. In one embodiment, the pre-cleaning solution may be acetone and a surfactant. The pre-cleaning may be followed by a distilled water rinse, particularly in an embodiment where a surfactant is used to prevent any surfactant remaining on the surface of the crystalline silicon substrate.

At block 120 of the flowchart of FIG. 1, the crystalline silicon substrate may be pre-treated with a hydrofluoric (HF) acid pre-treatment. The HF pre-treatment may aid in the removal of wire saw lines and damage to the surface of the crystalline silicon substrates and also in the removal of any native oxide on the surface of the crystalline silicon substrates. In certain embodiments, the HF pretreatment in combination with the texturing of the crystalline silicon substrate improves solar cell to cell texture uniformity. The HF pre-treatment solution may have a concentration in the range of 80:1 to 120:1 water (DI) to HF. The temperature of the HF pre-treatment solution may be room temperature (approximately 25° C.) or higher. In an embodiment, the HF pre-treatment solution may be 100:1 water (DI) to HF and may be pre-heated to a temperature of approximately 25° C. This HF pre-treatment solution can be applied to the substrate for a time sufficient to remove any wire saw damage and contaminants, and in one particular embodiment, for a time of approximately 1 minute.

At block 130 of the flowchart of FIG. 1 the c-Si substrate is textured with a texturing solution formed of potassium hydroxide (KOH), a short chain alcohol, and water. The texturing solution may be formulated to tune the resulting texture formed on the surface of the crystalline silicon substrate. The parameters that may be used to tune the texture formed include pyramid height, surface roughness, kurtosis, pyramid distribution, complete texturizing of the surface (whether there are any flat untextured areas), pyramid uniformity, pyramid angle, and micro-texture. Also, the texturing solution may be formulated to control the depth of the silicon etched during the texturing process before pyramids are formed on the surface. For example, the depth of the silicon etched before pyramid formation may be in the approximate range of 2-30 um (micrometers), and more particularly in the approximate range of 5-10 um. The pyramid height (perpendicular from base to peak) may be in the approximate range of 2-10 um, and more particularly in the approximate range of 3-5 um.

The KOH may have a concentration in the approximate range of 0.2 M (molar) to 3.0 M, and more particularly in the range of 0.5 M to 1.5 M. The concentration selected relates to other parameters such as temperature of the texturing solution and the time that the texturing solution is applied to the crystalline silicon substrate. The concentration of KOH may be selected to provide a particular texture on the crystalline silicon substrate, that texture being a surface covered with pyramid structures. The size of the pyramids may be tuned by the concentration of the KOH. Also, the concentration of the KOH may be kept low to ensure true anisotropic etching of the crystalline silicon surface and the formation of pyramids.

The texturing solution also includes a short chain alcohol having between 4 and 7 carbons and at least one hydroxyl group, but more particularly between 1-2 hydroxyl groups. Short chain alcohols may preserve the anisotropic etching characteristics of the texturing solution to produce pyramid structures on the surface of the crystalline silicon substrate. Examples of short chain alcohols that may be used include methanol, butanol, ethanol, and cyclo-pentanol. In one particular embodiment the short chain alcohol is a butanol compound selected from the butanol family, which is defined as any compound having at least 4 carbons and at least one alcohol (hydroxyl) group. Various types of butanol compounds may be used in the texturing solution. In an embodiment, the butanol compound may be 1-butanol, or a branched butanol compound such as 2-butanol, methoxy-butanol or ethoxy-butanol. Another butanol compound that may be used is cyclo-butanol having 1-3 hydroxyl groups.

The texturing solution may also include an additive. Examples of additives are other alcohols such as another short chain alcohol such as benzyl alcohol or 1-propanol, an amine such as dipropylamine, or a glycol such as ethylene glycol or propylene glycol. These additives may be included in the texturing solution to tune the texturing and the profile of the structures formed on the surface of the crystalline silicon substrate such as the pyramid size, pyramid distribution, pyramid uniformity, and roughness. Another additive that may be included in the texturing solution is silica. Silica may be added to the texturing solution in small amounts to nucleate pyramid formation and increase the rate of texturing. Adding silica may be of particular value to a process where the texturing solution is dispensed onto the crystalline silicon substrate because the addition of silica from the crystalline silicon substrate itself in the course of texturing may not occur to the same extent as when the crystalline silicon substrate is immersed in a bath. Silica may be added to a dissolved into the texturing solution in the approximate concentration of 2 g/L to 100 g/L. Silica may also be added to increase the efficiency of the texture formation because it may serve as a micro-mask for the formation of pyramids. With the addition of silica to the texturing formulation, it may be possible to texture a surface of a crystalline silicon substrate in less than 5 minutes.

The texturing solution may be applied to the crystalline silicon substrate by immersion, spraying, dispense, or curtain dispense. The time that the texturing solution is applied to the crystalline silicon substrate may be in the approximate range of 3 minutes to 40 minutes, and more particularly in the range of 5 minutes to 15 minutes. The temperature of the texturing solution may be in the approximate range of 60° C.-95° C. The range of 65° C.-70° C. may be used if a low temperature process is desired. The time may be related to the temperature of the texturing solution because the texturing may be faster at higher temperatures. For example, in a texturing solution formed of 1.0M KOH and between 3-5 volume % 1-butanol at 90° C. the texturing may be complete in approximately 10 minutes. The time and temperature selected may vary depending on the formulation of the texturing solution and the texture profile that one is trying to achieve.

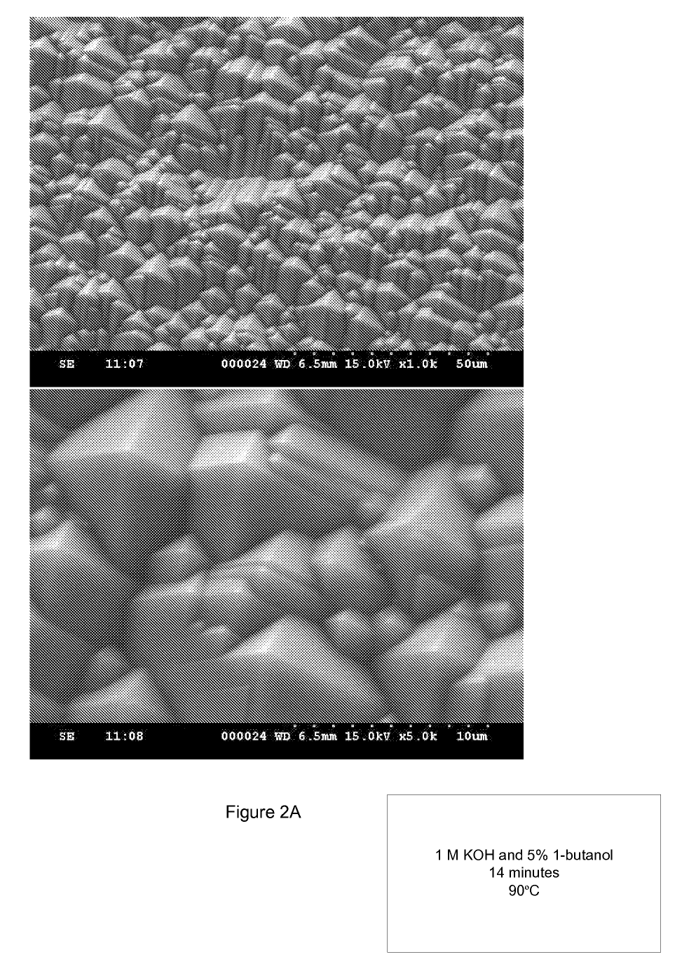

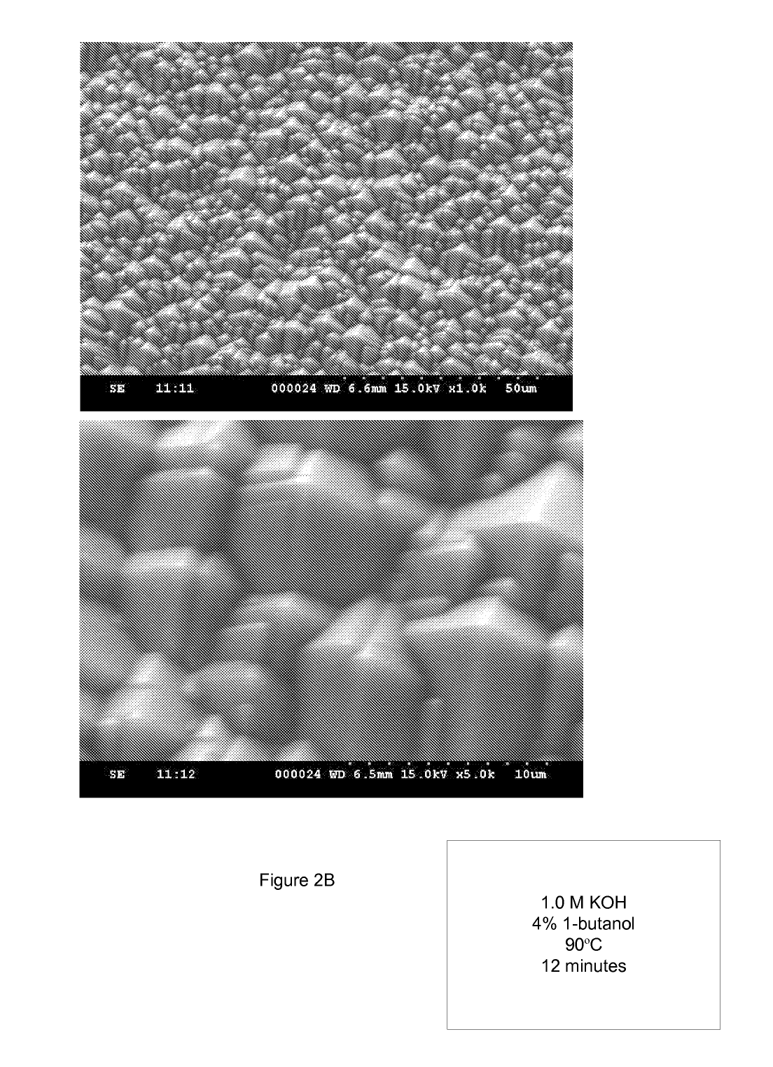

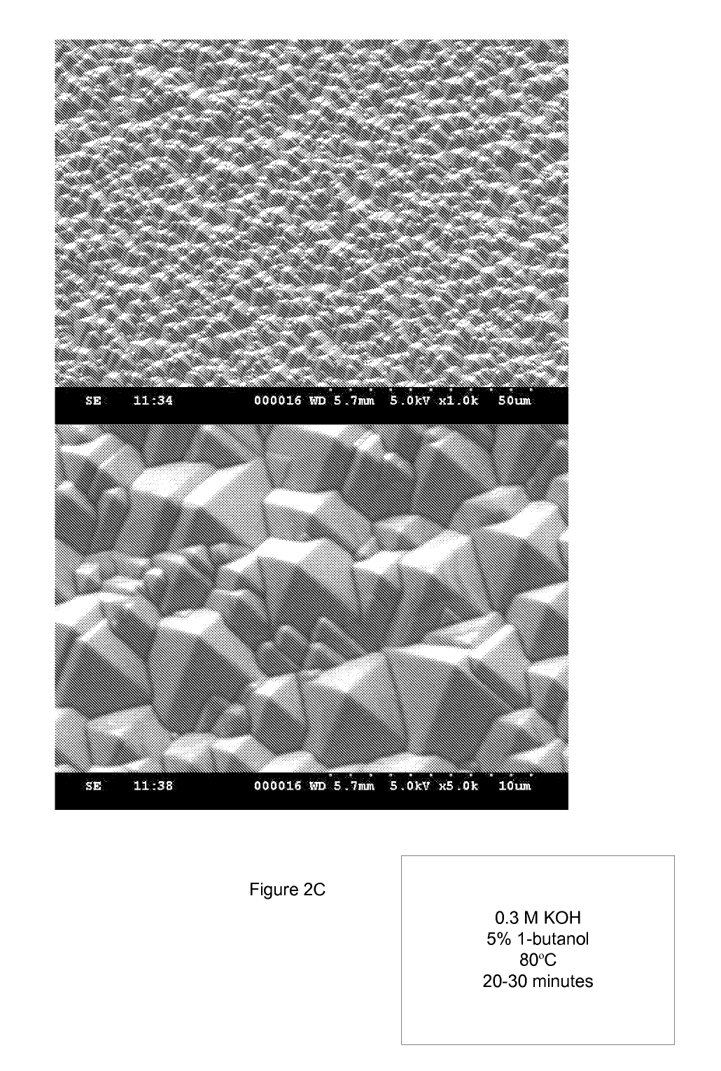

In one embodiment, the texturing solution may be approximately 0.5M KOH and approximately 5 volume % 1-butanol. The temperature of this solution may be approximately 90° C. A texture having good light trapping characteristics may be produced by this texturing solution by applying the solution while controlling the amount of butanol evaporation for 40 minutes. Examples of the texture formed by different formulations of KOH and 1-butanol are illustrated in FIGS. 2A-2C which are each a SEM (scanning electron microscope) photograph of the textured surface of a crystalline silicon substrate.

After texturing, the crystalline silicon substrate may optionally be rinsed with DI water at block 140 of the flowchart in FIG. 1 to remove the texturing solution from the surface. Alternately, or in addition to the water rinse, a dilute hydrofluoric (HF) acid solution may be applied to the crystalline silicon substrate at block 150 to neutralize the KOH in the acidic texturing solution to stop the texturing of the substrate. This allows for greater control of the resulting texturing on the crystalline silicon substrate and can increase substrate to substrate uniformity in the texturing. The dilute HF in water solution may have a concentration low enough not to etch the silicon. The dilute HF solution may be applied to the crystalline silicon substrate for a time sufficient to neutralize the acidic texturing solution and to stop the texturing.

At block 160 a post-texturing treatment may be performed to remove any residues from the crystalline silicon substrate. The removal of the residues may improve the performance of the solar cell that is ultimately formed from the textured crystalline substrate because they cannot block light from entering the textured crystalline silicon substrate or act as a dielectric, blocking the pathway of the current generated within the silicon substrate. The post-texturing treatment may be a strong acid such as hydrofluoric acid or sulfuric acid. The concentration of the strong acid may be an amount sufficient to remove the residues from the textured surface. In an embodiment where the texturing solution used at block 130 is approximately 0.5M KOH and approximately 5 volume % 1-butanol, at a temperature of approximately 90° C., and applied to the substrate for approximately 40 minutes, the post-texturing treatment may have a concentration of 1.0 weight % HF in water at room temperature (approximately 25° C.) may be applied to the crystalline silicon substrate for approximately 2.0-3.5 minutes. The application of this dilute HF post-texturing treatment may remove residues and a network of residues remaining after the texturing with the texturing solution. The residues removed are hypothesized to be Si(OH)₄ polymerization because they are easily removed by the post-texturing treatment in a short enough time not to etch the textured crystalline silicon substrate.

Solar cells may subsequently be formed from the textured crystalline silicon substrate. The texturing may be optimized to maximize the light trapping capabilities of the solar cells. The texturing solution described above may be optimized to tune the textured surface to have a predetermined texture profile that can provide maximized light trapping for a solar cell. The optimization of the texturing solution may be accomplished by a combinatorial workflow developed to screen many texturing solutions having different compositions, temperatures, and application times to a crystalline silicon substrate.

Combinatorial Methodology

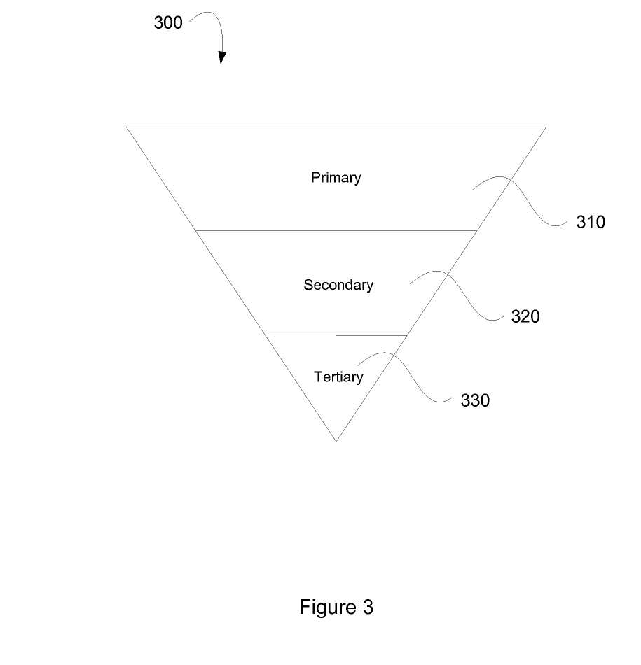

Combinatorial processing may include any processing that varies the processing conditions in two or more regions of a substrate. The combinatorial methodology, in embodiments of the current invention, includes multiple levels of screening to select the texturing solutions for further variation and optimization. In an embodiment, the texturing solution is optimized to provide the optimal light-trapping texture on the surface of a crystalline silicon substrate. FIG. 3 illustrates a diagram 300 showing three levels of screening for the development of the texturing solution using combinatorial methodologies. The diagram 300 shows a funnel, where the primary screening 310 includes the largest number of samples of texturing solutions funneling down to the secondary screening 320 and the tertiary screening 330 where the least number of samples of the texturing solutions are tested. The number of samples used at any of the screening levels may be dependent on the substrate or tools used to process the samples.

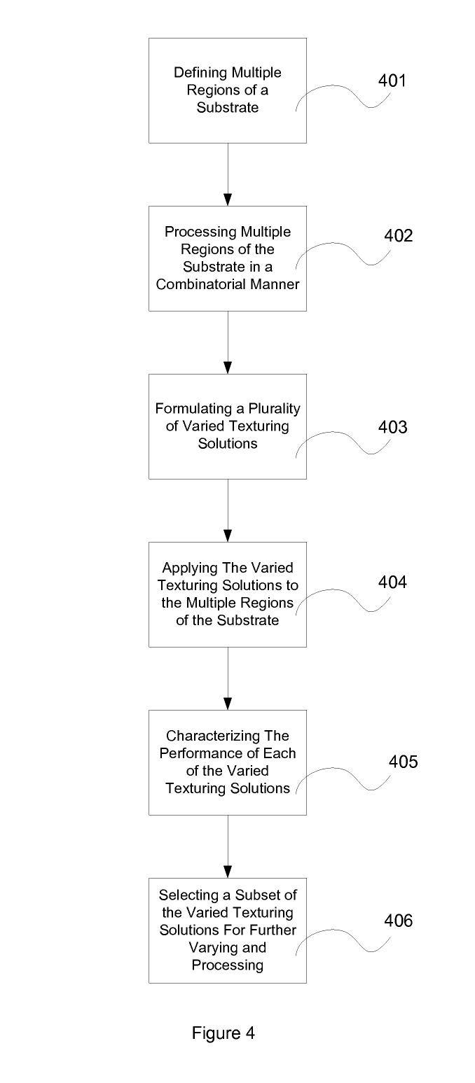

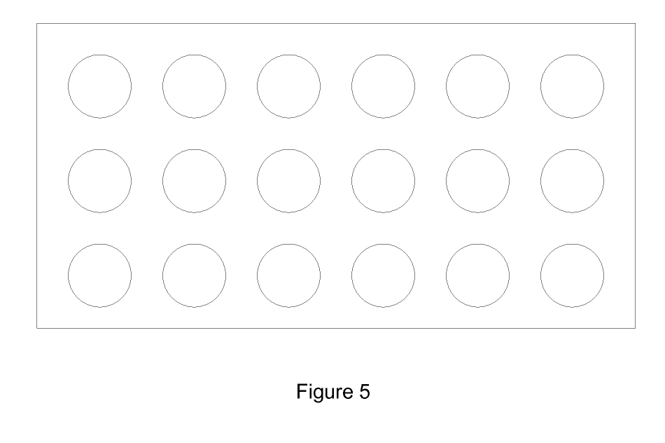

In an embodiment of the current invention, the screening at the different levels of the funnel is designed to formulate a texturing solution that is optimized to provide a particular texture profile on the surface of a crystalline silicon substrate. At the primary screening level 310 of this embodiment, the texturing solution is combinatorially screened in a high throughput manner to determine pyramid size and density, defects, light absorption, and etch rate of silicon by the different texturing solutions. The combinatorial screening process used is as outlined in the flowchart illustrated in FIG. 4. At block 401 of the flowchart of FIG. 4, the method begins by first defining multiple regions 510 of a crystalline silicon substrate 500 as illustrated in FIG. 5. A region of the substrate may be any portion of the substrate that is somehow defined, for example by dividing the substrate into regions having predetermined dimensions or by using physical barriers, such as sleeves, over the substrate. The region may or may not be isolated from other regions. In the embodiment illustrated in FIG. 5, the regions 510 may be defined by multiple sleeves that are in contact with the surface of the crystalline silicon substrate 500. The number of regions 510 defined by sleeves is only limited by the tools used for the combinatorial processing. As such, multiple experiments may be performed on the same substrate, and any number of regions may be defined. For example, five texturing solutions may be tested using fifteen regions of a substrate, each cleaning solution being tested three times.

In this embodiment, the substrate 500 may be a multi-crystalline or monocrystalline silicon substrate where each of the multiple regions 510 is textured using varied texturing solutions. At block 402 of the flowchart in FIG. 4, the multiple regions 510 of the substrate 500 are processed in a combinatorial manner. In an embodiment, this is done by formulating a plurality of varied texturing solutions. In one embodiment, this involves formulating multiple texturing solutions having methodically varied components (such as the base or the alcohol) by varying at least one of the chemical components of the texturing solution. The varied chemical component may also have varied concentrations. At block 404, the varied texturing solutions are applied to the multiple regions 510 of the substrate 500. A single varied texturing solution is applied to each of the multiple regions 510 for a predetermined amount of time.

At block 405, the performance of each of the varied texturing solutions is characterized. The characterization is performed to determine how effectively each of the varied texturing solutions textures the crystalline silicon substrate at each of the regions 510. The characterization may first be performed by a visual analysis of the textured regions with a scanning electron microscope (SEM). The optical microscopy images will provide the information about the pyramid density, whether texturing has occurred, whether the texturing covers all of the surface or whether there are flat areas between the texturing. The size of the pyramids may also be determined through the visual analysis. For each region, multiple images may be taken to determine whether the texturing is uniform across the region. The reflectance of the textured surface of each of the regions is then measured using a UV-Vis spectrometer (a spectrometer measuring light reflectance from the ultraviolet (UV) range to the visible range of the spectrum.) From this reflectance data it can be determined how well the texture traps, or absorbs, light. The lower the reflectance, the more absorption. From these images in combination with the UV-Vis spectrometer data it can be determined whether the texturing is sufficient to proceed to the next combinatorial screening step, which may also be part of the primary screening or may be secondary screening.

In some embodiments, the etch rate of the cleaning solution is determined by how much of the surface of the silicon substrate is etched before texturing occurs. The amount of silicon etched before texturing occurs may be determined by using a profilometer to compare the height of the un-etched areas between the test regions to the depth etched within the test regions. In this example, if a texturing solution removes too much of the surface before texturing occurs, then it is screened out of consideration.

The screening then includes a second characterization of the regions 510 where the texturing appeared to be uniform across the substrate based on the SEM images and the UV-Vis spectrometer data. The regions 510 where the texture appeared to be uniform are then characterized by AFM measurements to evaluate the roughness, skewness, and kurtosis of the substrate. The AFM measurements have a resolution on the order of micrometers and may provide more detailed information on the texture on a finer scale. The AFM measurements provide the root means square (rms) average of the roughness of a region of the substrate to provide a measure of the roughness of the surface in nanometers. Using the AFM information, a subset of the varied cleaning solutions is then selected for further varying and processing at block 406 of the flowchart in FIG. 4. A subset of cleaning solutions is selected based on which texturing solutions have the highest roughness values because higher roughness indicates higher randomness in the pyramid size and randomness in the pyramid distribution, both of which provide the best light trapping.

The combinatorial methodology then funnels down to the secondary screening 320 of FIG. 3. The subset of selected cleaning solutions from the primary screening 310 is then tested on another crystalline silicon substrate. The secondary screening uses the same methodology as the primary screening, as outlined in the flowchart of FIG. 4. After defining the multiple regions on the crystalline silicon substrate, using similar methods as described above with relation to FIG. 5, the multiple regions are processed in a combinatorial manner at block 402. The processing in a combinatorial manner is performed by formulating a plurality of varied texturing solutions at block 403 based on the subset of texturing solutions selected at the end of the primary screening process. In an embodiment, the subset of texturing solutions is varied to test the process space of the chemical compositions that were identified as having the best texturing in the primary screening. For example, the temperature and time of the compositions may be varied. At block 404 these selected texturing solutions are applied to the multiple regions of the crystalline silicon substrate to determine process space for each composition.

The performance of each of the texturing solutions applied to the multiple regions of the substrate is then characterized at block 405. The characterization is done through the same process as described above in relation to the primary screening. In an embodiment, the textured crystalline silicon surfaces may first be visually analyzed using SEM photographs to eliminate any of the texturing solutions that did not uniformly texture pyramids (no flat areas), did not produce pyramids within the range of predetermined sizes, or produced visible defects. Optical measurements with the UV-Vis spectrometer may then be made to determine whether the reflectance is within a predetermined range. Profilometer measurements may also be made to determine whether the etching of the silicon is minimal and less than a predetermined amount. At block 406 a subset of the varied texturing solutions is selected for further varying and processing based on the characterization data. AFM measurements are then taken of the texturing solutions that meet the predetermined characteristics measured visually by SEM, optically by UV-vis spectrometry, and by the profilometer. A subset of the texturing solutions for which it was found that the roughness of the texture was within a predetermined range based on the AFM measurements may undergo further primary and secondary screening to narrow down the results for tertiary screening 330 or the subset may directly go to tertiary screening 330.

The tertiary screening level 330 of the combinatorial funnel will perform the final screening of the texturing solutions where the textured crystalline silicon substrates are used to build solar cells. In an embodiment, the number of texturing solutions at this screening level may be less than ten, in one particular embodiment the number of texturing solutions may be one or two, but could be any number. The final screening will optimize the texturing solution to texture a crystalline silicon substrate that is used to build a solar cell. Electrical data from these solar cells can be analyzed in the characterization of the performance of the texturing solutions at the tertiary screening level to identify which texturing formulations provide the electrical results within a predetermined range. The texturing solutions identified in the tertiary screening level may then be scaled up to be used in the manufacturing of commercial-grade solar cells.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method of texturing a crystalline-silicon (c-Si) substrate, comprising:
pretreating the c-Si substrate with a hydrogen fluoride solution; and
texturing the c-Si substrate with a texturing solution consisting essentially of KOH and butanol.

2. The method of claim 1, wherein the substrate is textured for a time sufficient to produce a plurality of pyramids having a height of 2 um to 10 um measured from height to base and a random distribution.

3. The method of claim 1, further comprising maintaining a temperature of the texturing solution in the approximate range of 70° C. and 90° C. during the texturing of the c-Si substrate.

4. The method of claim 1, wherein the c-Si substrate comprises a multicrystalline substrate.

5. The method of claim 1, wherein pretreating the c-Si substrate comprises applying the hydrogen fluoride solution having a ratio of water:HF of approximately 100:1.

6. The method of claim 1, further comprising pre-cleaning the c-Si substrate with a pre-cleaning solution to remove organic contaminants before texturing the c-Si substrate with the texturing solution.

7. The method of claim 1, further comprising applying a dilute acid rinse to the c-Si substrate after applying the texturing solution to neutralize the texturing solution.

8. The method of claim 1, further comprising applying a hydrofluoric acid (HF) post-treatment to the c-Si substrate after texturing the c-Si substrate.

9. The method of claim 1, further comprising applying a water rinse to the c-Si substrate after texturing the c-Si substrate.

10. A crystalline silicon texturing formulation, consisting essentially of:
KOH in a concentration of less than approximately 1.5 M;
butanol in a concentration in the approximate range of 2-8 volume percent, wherein the formulation has a temperature in the approximate range of 60° C. and 100° C.; and
water.

11. The formulation of claim 10, wherein butanol comprises 1-butanol.

12. The formulation of claim 10, wherein butanol comprises 2-butanol.

13. The formulation of claim 10, wherein the concentration of KOH is approximately 0.2 M, the butanol comprises 1-butanol having a concentration of approximately 5%, and the temperature of the formulation is approximately 90° C.

14. The formulation of claim 10, further including silica in an amount sufficient to increase the texturing rate (or to initiate pyramid formation).

15. A combinatorial method of tuning a silicon texturing solution to texture a crystalline silicon substrate to have predetermined characteristics, comprising:
screening a plurality of silicon texturing solutions having varied concentrations to identify a first subset of silicon texturing solutions that provide a texture on a c-Si substrate, wherein the texture comprises pyramids having a height and a distribution within a predetermined range;
screening the first subset of silicon texturing solutions having varied temperatures and substrate application times to identify a second subset of silicon texturing solutions capable of etching the c-Si substrate within a predetermined time;
screening the second subset of silicon texturing solutions having varied formulations by applying the second subset to substrates that are larger than substrates used for screening the plurality of silicon texturing solutions and the first subset of silicon texturing solutions, wherein the second subset is selected based on an ability of the texturing solution to provide a texture on the c-Si substrate having optical reflection measurements within a predetermined range

16. The method of claim 15, wherein the screening comprises measuring the roughness, pyramid/texture distribution (density), pyramid/texture size, kurtosis, optical reflectance, etch thickness, pyramid/texture uniformity.

17. The method of claim 15, wherein the first subset of texturing solutions are selected to etch less than 30 um of silicon from the surface of the c-Si substrate.
